(19) United States
(12) Patent Application Publication
(10) Pub. No.: US 2022/0017251 A1
(43) Pub. Date: Jan. 20, 2022

(54) Method and System for Automating Computer System Component Serialization

(71) Applicant: Dell Products L.P., Round Rock, TX (US)

(72) Inventors: Philip Nolan, Cork (IE); Desmond O'Regan, Cork (IE); Kieran Kelly, Cork (IE); Denis Hurley, Cork (IE)

(73) Assignee: Dell Products L.P., Round Rock, TX (US)

(21) Appl. No.: 16/930,834

(22) Filed: Jul. 16, 2020

(51) Int. Cl. B65C 1/02; B65C 9/42; B65C 9/18; B65C 9/26

(52) U.S. Cl. CPC B65C 1/021; B65C 9/26; B65C 9/1865; B65C 9/42

(57) ABSTRACT

A system, method, and computer-readable medium are disclosed for automated component serialization. A group of components that are of the same component to be used in a computer system are identified. One of the components is separated and labeled with serialization information. The labeled serialized information is verified and entered into an enterprise resource planning system. The process continues until all the group of components are labeled and verified.

### BACKGROUND OF THE INVENTION

### Field of the Invention

The present invention relates to manufacturing of computer systems. More specifically, embodiments of the invention relate to automation of component serialization in the manufacturing and integration of computer systems.

### Description of the Related Art

In manufacturing and integration of computer systems, such as server computers, workstations, laptop computers, etc., different parts and sub-systems, collectively referred to as components, may be sourced from various suppliers. In other words, the same component integrated into a computer system may be sourced from different suppliers. Each of the suppliers can have their own particular identification or part number for the component. The component may come from a supplier with a label indicating the supplier part number.

Component serialization includes the process of identifying and registering components with a manufacturer's part number, serial number, and other information in order to track components. For example, component serialization can be implemented in an enterprise resource planning (ERP) system that manages resources such as components that are installed in manufacturer products such as computer systems.

A manufacturer that implements component serialization typically receives different components from the various manufacturers, determines which part number, serial number, and other information that is needed to “serialize” the component, and the information into an ERP system. This can be a long and tedious process involving considerable resources.

### SUMMARY OF THE INVENTION

A system, method, and computer-readable medium are disclosed for automated component serialization. A group of components that are of the same component to be used in a computer system are identified. One of the components is separated and labeled with serialization information. The labeled serialized information is verified and entered into an enterprise resource planning system. The process continues until all the group of components are labeled and verified.

### BRIEF DESCRIPTION OF THE DRAWINGS

The use of the same reference number throughout the several figures designates a like or similar element. The present invention may be better understood, and its numerous objects, features, and advantages made apparent to those skilled in the art by referencing the accompanying drawings, wherein:

FIG. 1 depicts a general illustration of a computing system as implemented in the system and method of the present invention;

FIG. 2 depicts an automated computer system component serialization system;

FIG. 3 shows a flow chart for component processing;

FIG. 4 shows a flow chart for processing component serialization; and

FIG. 5 shows a flow chart for automated component serialization.

### DETAILED DESCRIPTION

A system, method, and computer readable medium are disclosed for automating component serialization in support of the manufacturing and integrating of computer systems. In various embodiments, component serialization is initiated when a multiple number of the same components are placed in a labeled component tray and are processed. The labeled component tray is scanned, identifying the particular component to be serialized. A component from the labeled component tray is placed in a component reader box and can be tested. A label is created for component serialization and is affixed to the component. The labeled component is placed back in the component tray and other components from the component tray are processed and labeled. The information from the labels that are affixed to the components can be provided to an enterprise resource planning (ERP) system.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

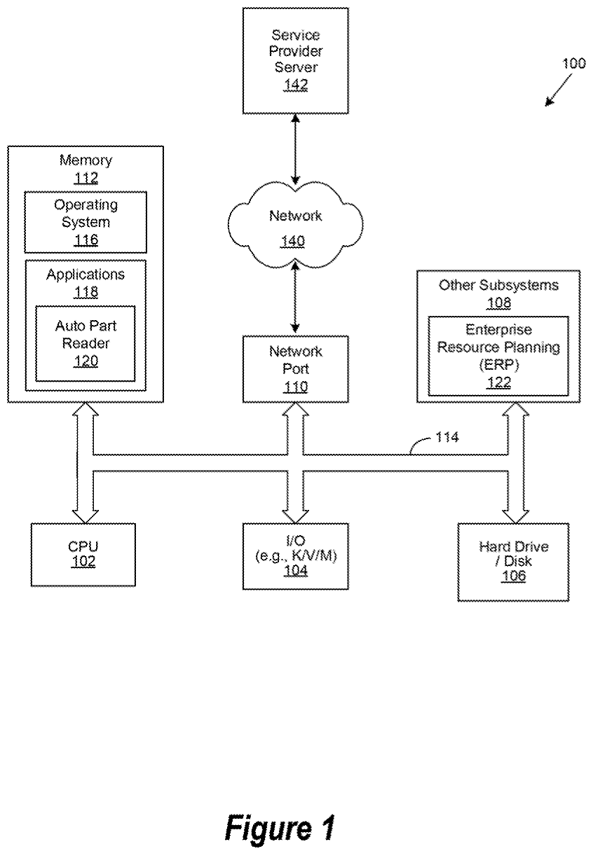

FIG. 1 is a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The network 140 may be a public network, such as the Internet, a physical private network, a wireless network, a virtual private network (VPN), or any combination thereof. Skilled practitioners of the art will recognize that many such embodiments are possible, and the foregoing is not intended to limit the spirit, scope or intent of the invention.

The information handling system 100 likewise includes system memory 112, which is interconnected to the foregoing via one or more buses 114. System memory 112 further includes an operating system (OS) 116 and applications 118. In certain embodiments, applications 118 are provided as a service from the service provider server 142.

Certain embodiments provide for applications 118 to include an automated part reader software application or auto part reader 120, and other subsystems 108 to include an enterprise resource planning (ERP) system 122. Auto part reader 120 and ERP system 122 are further described herein.

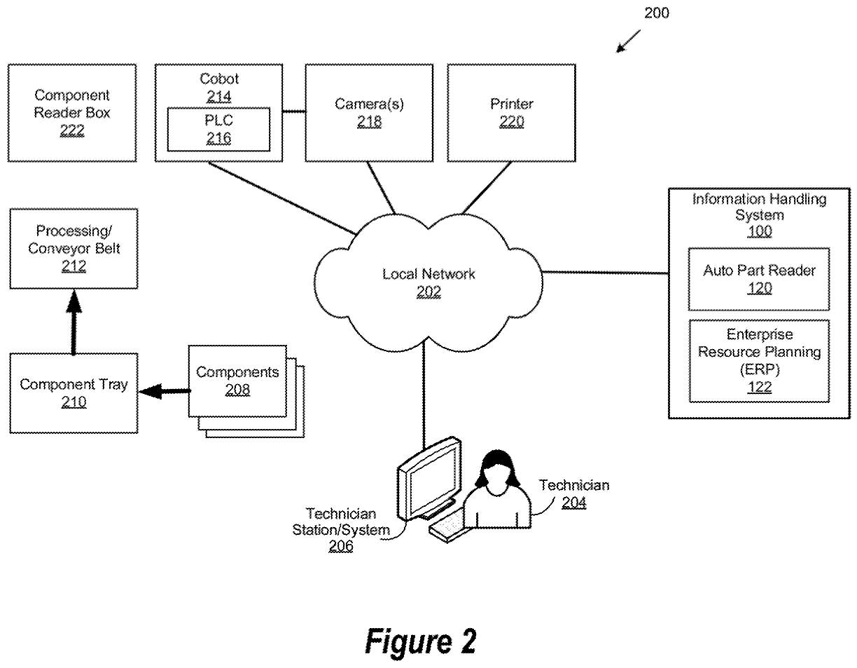

FIG. 2 is a simplified block diagram of a system for an automated computer system component serialization. The system 200 includes the information handling system 100 which includes auto part reader 120 and ERP 122. In certain implementations, the information handling system 100 connects with other devices and systems of the system 100 through a local network 202. It is also to be understood, that other implementations provide for direct connection of the information handling system 100 and other devices and systems of the system 100.

Certain implementations provide for a technician 204 through a technician station/system 206 to connect with the information handling system 100. In particular, the technician 204 can control or implement the use of auto part reader 120 and ERP during an automated component serialization process.

In various implementations, components 208 from various different suppliers are received for component serializations. An example of components 208 are dual in-line memory modules or DIMM, which are mounted on a printer circuit board (PCB) and used in computing systems, such as personal computers, work stations and servers. Components 208, such as DIMMs, may be received from different suppliers or vendors by the manufacturer, and are considered as “raw” parts that are to be serialized and made transactable in the manufacturer's ERP 122.

In certain implementations, the components 208 are loaded into a component tray 210. A multiple number of the components 208 can be loaded into component tray 210. For example, there can be 40 DIMMs loaded into component tray 210. Certain implementations provide for the component tray 210 with loaded components 208 to be placed on a processing/conveyor belt 212.

In various implementations the system 200 includes a collaborative robot or cobot 214. The cobot 214 can be controlled through programmable logic control or PLC 216. In particular, the cobot 214 through PLC 216 communicates with information handling system 100, either directly or through network 202. Cobot 214 directly or through network 202 implements the use of camera(s) 218. Implementations further provide for the system 200 to include a printer 220 which can be controlled by information handling system 100.

In certain implementations, component trays 210 are affixed with a part number label. Loaded component trays 210 on processing/conveyor belt 212 are moved into position and the part number label on the component trays 210 is scanned by camera(s) 218 as to the part number. The part number may be a barcode or other machine readable code. Scanning of the part number can invoke the information handling system 100, and particularly the auto part reader 120 to process (i.e., serialize) the components 208 based on the scanned part number.

Once the part number on the part number label of the component tray 210 is scanned and identified, in certain implementations, the cobot 214 is instructed to pick up a component 208 from the component tray 210 and place the component 208 into a component reader box 222. In certain implementations, the component reader box 222 can provide for component testing, for example test slots for DIMMs, where testing can involve running various test sequences on the component 208 (e.g., DIMM).

Various implementations can provide for printer 220 to print a label (e.g., barcode label) for component serialization to be used by ERP 122. In certain implementations, cobot 214 retrieves the printed label and affixes the printed label onto the component 208 on the component reader box 222. The affixed label is read by camera(s) 218 and the information of the label is entered/registered into ERP 122. The processed component 208 can be placed back into the component tray 210. Succeeding components 208 are processed until all components 208 in the component tray 210 are labeled and information entered into ERP 122.

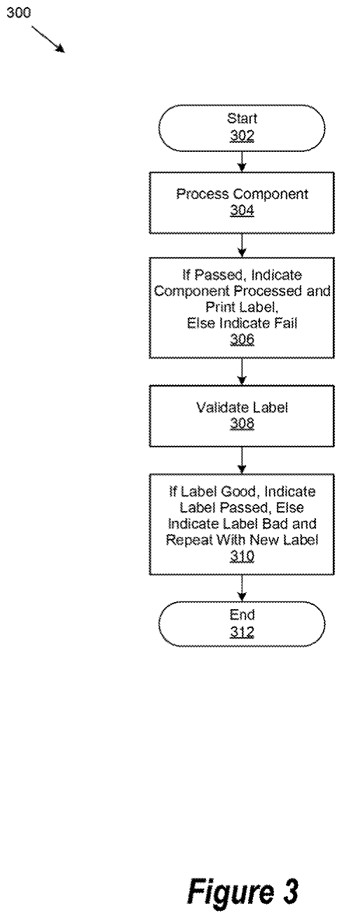

FIG. 3 is a generalized flowchart 300 for component processing. The order in which the method is described is not intended to be construed as a limitation, and any number of the described method blocks may be combined in any order to implement the method, or alternate method. Additionally, individual blocks may be deleted from the method without departing from the spirit and scope of the subject matter described herein. Furthermore, the method may be implemented in any suitable hardware, software, firmware, or a combination thereof, without departing from the scope of the invention.

At step 302, the process 300 starts. At step 304, a component is processed. As discussed, the component can be components 208 and used in the manufacturing or integration/assembly of computing systems, such as personal computers, work stations and servers. An example of components are dual in-line memory modules or DIMM. Processing as described herein can include receiving the component as “raw” pats or subsystems from various suppliers. In certain implementations, processing can be initiated by an operator, such as technician 204.

At step 306, a determination is made if the component passes the processing of step 304. The determination can include the component passing a test sequence or sequences. If the component passes the processing, a label can be printed for the component. The label is affixed to the component. The label includes information as to the component, that can be used or registered into an enterprise planning resource (ERP) system, such as ERP 122.

At step 308, a validation is performed on the affixed label. The validation can include scanning the affixed label as discussed above and determining if the information is correct or acceptable for the ERP system.

At step 310, a determination is made if the label is good. If the label is good, indication is made that the label passes. Otherwise, if the label is bad, a new label can be repeated to be affixed to the component. At step 312, the process 300 ends.

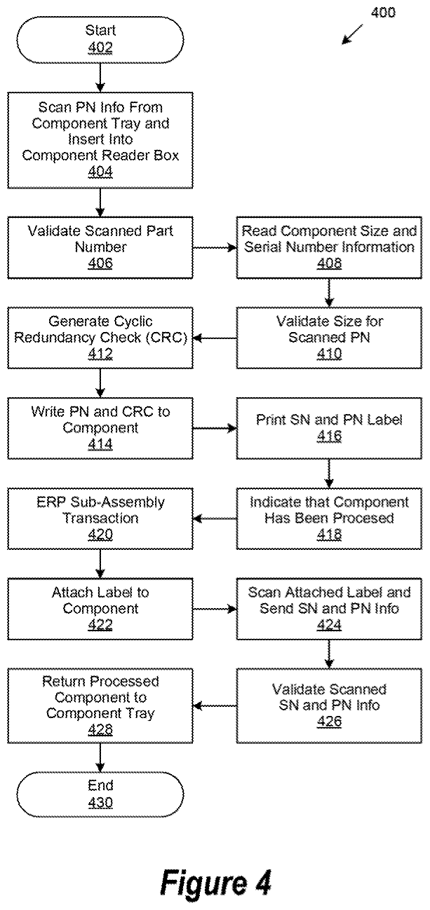

FIG. 4 is a generalized flowchart 400 for processing component serialization. The order in which the method is described is not intended to be construed as a limitation, and any number of the described method blocks may be combined in any order to implement the method, or alternate method. Additionally, individual blocks may be deleted from the method without departing from the spirit and scope of the subject matter described herein. Furthermore, the method may be implemented in any suitable hardware, software, firmware, or a combination thereof, without departing from the scope of the invention.

At step 402, the process 400 starts. The process 400 may be initiated by an operator, such as technician. Throughout the process 400, it is to be understood, that the operator can interrupt or pause the process 400.

At step 404, a component tray 210 that includes several components 208 is scanned. In particular, an affixed label on the component tray 210 is scanned and read. The affixed label can include part number and other information, such as size, dimensions, configuration etc. related to the components 208. Scanning can be performed by camera(s) 218 as described herein. A component 208 is removed from the component tray 210 and placed in a component reader box 222. In certain implementations, cobot 214 removes and places the component 208 into component tray 210. In various implementations, the cobot 214 through PLC 216 provides the scanned part number to information handling system 100 and particularly to auto part reader 120 to indicate that the component 208 is ready for processing.

In various implementations the auto part reader performs the following steps 406 to 420. At step 406, the scanned part number is validated. At step 408, component size and serial number from the scanned label is read. At step 410, the size of the component is validated per the part number. At step 412, a cyclic redundancy code (CRC) is generated. At step 414, the part number and CRC as the component is written/recorded. At step 416, an instruction is sent to printer 220 to print a label with manufacturer serial number and part number to be affixed to the component 208. At step 418, an indication is provided that the component 208 has been processed. The indication can be provided to the cobot 214 through the PLC 216. At step 420, an ERP 122 sub-assembly transaction is performed.

At step 422, the label that was instructed to be printed at step 416 is affixed/attached to the component 208. The affixing/attaching can be performed by cobot 214. At step 424, the affixed/attached label on component 208 is scanned by camera(s) 218. At step 426, validation of the affixed/attached label is performed. Validation can be performed by the auto part reader 120.

At step 428, the processed component 208 is returned to the component tray 210, and a subsequent component 208 can be processed, until all the components 208 in the component tray are processed. At step 430, the process 400 ends.

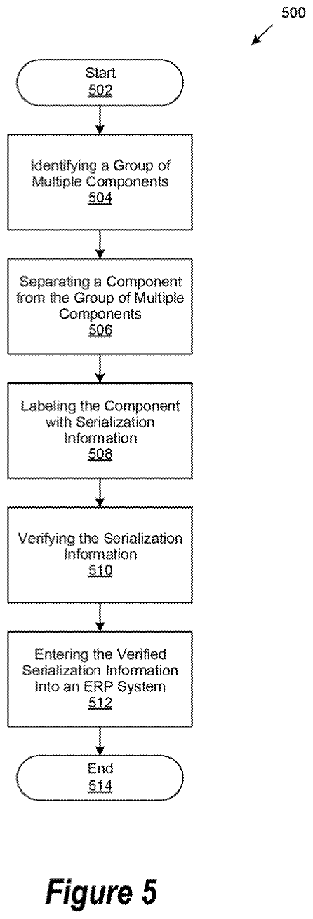

FIG. 5 is a generalized flowchart 500 for automated component serialization. The order in which the method is described is not intended to be construed as a limitation, and any number of the described method blocks may be combined in any order to implement the method, or alternate method. Additionally, individual blocks may be deleted from the method without departing from the spirit and scope of the subject matter described herein. Furthermore, the method may be implemented in any suitable hardware, software, firmware, or a combination thereof, without departing from the scope of the invention.

At step 502, the process 500 starts. At step 504, identifying a group of multiple components, such as components 208, is performed. The multiple components are a particular component, where the particular components can be implemented in a computer system. In certain implementations, the multiple components are in a component tray 210. Identifying can be performed by scanning a label affixed to the component tray 210 by camera(s) 218.

At step 506, separating one of the components of the multiple components is performed. The separating can be performed by a cobot 214 and the separated component can be placed in a component reader box 222. While in component reader box 222, additional testing of the component can be performed.

At step 508, labeling the component with serialization information is performed. The label can be printed from a printer 220 and affixed by the cobot 214. Serialization information can include manufacturer part number, component size, component dimension and component configuration information.

At step 510, the verifying the serialization information is performed. Verifying may be performed by scanning the information on the label of the component by camera(s) 218.

At step 512, entering the verified serialization information into an enterprise resource planning (ERP) system is performed. The process 500 can continue until all the multiple components are processed and labeled. At step 514, the process 500 ends.

As will be appreciated by one skilled in the art, the present invention can be embodied as a method, system, or computer program product. Accordingly, embodiments of the invention can be implemented entirely in hardware, entirely in software (including firmware, resident software, micro-code, etc.) or in an embodiment combining software and hardware. These various embodiments can all generally be referred to herein as a “circuit,” “module,” or “system.” Furthermore, the present invention can take the form of a computer program product on a computer-usable storage medium having computer-usable program code embodied in the medium.

Any suitable computer usable or computer readable medium can be utilized. The computer-usable or computer-readable medium can be, for example, but not limited to, an electronic, magnetic, optical, electromagnetic, infrared, or semiconductor system, apparatus, or device. More specific examples (a non-exhaustive list) of the computer-readable medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, or a magnetic storage device. In the context of this document, a computer-usable or computer-readable medium can be any medium that can contain, store, communicate, or transport the program for use by or in connection with the instruction execution system, apparatus, or device.

Computer program code for carrying out operations of the present invention can be written in an object oriented programming language such as Java, Smalltalk, C++ or the like. However, the computer program code for carrying out operations of the present invention can also be written in conventional procedural programming languages, such as the “C” programming language or similar programming languages. The program code can execute entirely on the user's computer, partly on the user's computer, as a stand-alone software package, partly on the user's computer and partly on a remote computer or entirely on the remote computer or server. In the latter scenario, the remote computer can be connected to the user's computer through a local area network (LAN) or a wide area network (WAN), or the connection can be made to an external computer (for example, through the Internet using an Internet Service Provider).

Embodiments of the invention are described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions can also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions can also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only and are not exhaustive of the scope of the invention.

Consequently, the invention is intended to be limited only by the spirit and scope of the appended claims, giving full cognizance to equivalents in all respects.

What is claimed is:

1. A computer-implementable method for automated component serialization, comprising:
identifying a group of multiple components, wherein the multiple components are a particular component that is implemented in a computer system;
separating a component form the group of multiple components;
labeling the component with serialization information;
verifying the serialization information; and
entering the verified information into an enterprise resource planning system.

2. The method of claim 1, wherein the multiple components are dual in-line memory modules.

3. The method of claim 1, wherein the identifying is performed by scanning a label on a component tray holding the multiple components, wherein the label identifies the particular component.

4. The method of claim 1, wherein the separating is performed by a cobot which places the component into a component reader box.

5. The method of claim 4 further comprising testing the component while in the component reader box.

6. The method of claim 1, wherein the labeling serialization information includes one or more of a manufacturer part number, component size, component dimensions, and component configuration.

7. The method of claim 1, wherein the verification is performed by scanning the label on the component.

8. A system comprising:
a processor;
a data bus coupled to the processor; and
a non-transitory, computer-readable storage medium embodying computer program code, the non-transitory, computer-readable storage medium being coupled to the data bus, the computer program code interacting with a plurality of computer operations and comprising instructions executable by the processor and configured for:
identifying a group of multiple components, wherein the multiple components are a particular component that is implemented in a computer system;
separating a component form the group of multiple components;
labeling the component with serialization information;
verifying the serialization information; and
entering the verified information into an enterprise resource planning system.

9. The system of claim 8, wherein the multiple components are dual in-line memory modules.

10. The system of claim 8, wherein the identifying is performed by scanning a label on a component tray holding the multiple components, wherein the label identifies the particular component.

11. The system of claim 8, wherein the separating is performed by a cobot which places the component into a component reader box.

12. The system of claim 11 further comprising testing the component while in the component reader box.

13. The system of claim 8, wherein the labeling serialization information includes one or more of a manufacturer part number, component size, component dimensions, and component configuration.

14. The system of claim 8, wherein the verification is performed by scanning the label on the component.

15. A non-transitory, computer-readable storage medium embodying computer program code, the computer program code comprising computer executable instructions configured for:
identifying a group of multiple components, wherein the multiple components are a particular component that is implemented in a computer system;
separating a component form the group of multiple components;
labeling the component with serialization information;
verifying the serialization information; and
entering the verified information into an enterprise resource planning system.

16. The non-transitory, computer-readable storage medium of claim 15, wherein the multiple components are dual in-line memory modules.

17. The non-transitory, computer-readable storage medium of claim 15, wherein the identifying is performed by scanning a label on a component tray holding the multiple components, wherein the label identifies the particular component.

18. The non-transitory, computer-readable storage medium of claim 15, wherein the separating is performed by a cobot which places the component into a component reader box.

19. The non-transitory, computer-readable storage medium of claim 15, wherein the labeling serialization information includes one or more of a manufacturer part number, component size, component dimensions, and component configuration.

20. The non-transitory, computer-readable storage medium of claim 15, wherein the verification is performed by scanning the label on the component.
